(19) United States
(12) Patent Application Publication
(10) Pub. No.: US 2015/0023866 A1
(43) Pub. Date: Jan. 22, 2015

(54) METHOD AND SYSTEM OF PRODUCING LARGE OXIDE CRYSTALS FROM A MELT

(71) Applicant: Rubicon Technology, Inc., Bensenville, IL (US)

(72) Inventors: Matthew Montgomery, Batavia, IL (US); Timothy D. Burks, Chicago, IL (US); Sergey Podlozhenov, North Aurora, IL (US); Jonathan Levine, Chicago, IL (US)

(73) Assignee: Rubicon Technology, Inc., Bensenville, IL (US)

(21) Appl. No.: 13/947,656

(22) Filed: Jul. 22, 2013

(51) Int. Cl. C30B 11/00; C30B 29/20

(52) U.S. Cl. CPC C30B 11/003; C30B 29/20; C30B 11/007
USPC 423/592.1; 117/81; 117/223

(57) ABSTRACT

A process and system may be employed to produce large, defect-free oxide crystals with high melting points which may utilize a water-cooled horizontal furnace with a hot zone design comprising multiple independently controllable heaters surrounded by a vapor shield and various layers of thermal insulation of varying thickness and composition. Raw materials such as sapphire crystals or alumina powder may be placed in a crucible or boat that may be positioned to ride on rollers. The crucible may be pulled (or pushed) through a furnace environment surrounded by a vapor shield and insulation at a controlled rate to melt and then crystallize the raw material into a sapphire crystal. The vacuum level may be controlled by a vacuum system attached to the furnace. Process parameters such as power, temperature, pulling speed (i.e., movement speed), heating rates, cooling rates, and chamber pressure may be controlled by a control system which may be configured to take an input from each component of the system and sends the necessary control outputs.

### STATEMENT REGARDING FEDERALLY SPONSORED RESEARCH OR DEVELOPMENT

This invention was made with government support under contract no. FA8650-12-C-5168 awarded by USAF/AFMC. The government has certain rights in the invention.

### BACKGROUND OF THE DISCLOSURE

1.0 Field of the Invention

The disclosure relates to the field of producing crystals from a melt and, more particularly, a system and method for producing crystals such as large sapphire crystals from a melt, among other features.

2.0 Related Art

Current techniques have several deficiencies including constrained or limited ability in producing large sized crystals, such as large sapphire crystals. In particular, there is an absence of large sapphire crystals greater than one inch in thickness. Moreover, the current crystal production techniques are prone to produce relatively large crystals of inconsistent quality and often have significant defects in the crystals produced.

These deficiencies may be related to one or more of the following issues:
Inability to adequately control heat supplied to the process of crystal production.
Inability to adequately control the convexity of the crystallization front.
Non-uniform heating of the heaters, especially in relation to non-uniform heat dissipation from the surface of a melt.
No ability to independently modify the size, shape and length of individual heating elements.
Limited thermal control over crystallization process.
Inefficient heater operations that require substantial power utilization.

A system and method for reducing or eliminating these deficiencies would permit better quality of crystals and much larger crystals, while requiring less power.

### SUMMARY OF THE DISCLOSURE

The present disclosure overcomes the limitations as discussed above and provides an improved process and system for producing crystals from a melt.

In one aspect, a process for producing large substantially defect free oxide crystals is provided including the steps of creating a pressurized or evacuated environment for heating a crucible having oxide material therein, moving the crucible from a main heater to at least one after heater on a pre-determined schedule, wherein the main heater and the at least one after heater are configured spaced apart from one another and configured to be independently controllable to heat the oxide material, adjusting the pressure of the environment at least once during the process and cooling the oxide material to produce a large oxide crystal. The process may further include adjusting a rate of movement of the oxide material during the movement step. The main heater may be configured to melt the oxide material to produce a melt and the spaced apart at least one after heater maintains a temperature gradient within a pre-determined threshold as the oxide is moved from the main heater through the at least one after heater to prevent stress in the crystal. The process may further include the step of seeding the oxide material to grow a crystal having a desired crystal orientation.

In one aspect, a process for producing large, defect-free oxide crystals with a high melting point is provided including the steps of: utilizing a fluid-cooled horizontal furnace with a hot zone produced by a plurality of independently controllable heaters each heater surrounded by a vapor shield and a plurality of thermal insulation layers to melt oxide material and to crystallize and grow the melted oxide into a large oxide crystal and cooling the grown large oxide crystal to ambient temperature. The utilizing step may include adjusting pressure in the fluid cooled horizontal furnace. The utilizing step may include the following stages: a) a heat up stage to heat the oxide material, the heat up stage ranging in duration time selected from the range of about 24 to about 72 hours wherein a temperature of the fluid-cooled horizontal furnace is selected from a range between about 20° C. and about 2200° C. and an environmental pressure selected from a range from about 5 Pascals to about 20 Pascals, b) a pre-melting stage to melt the oxide material; the pre-melting stage duration may be selected from a range from about 12 to about 18 hours and an environmental pressure is selected from a range of about 10 Pascals to about 20 Pascals, and a speed of movement of the oxide material though the hot zone is about 60 mm/hr, c) a seeding stage to permit the melted oxide material to begin to crystallize; the seeding stage of oxide movement speed selected from the range of about 8 mm/hr to about 15 mm/hr. and a environmental pressure selected from a range from about 5 Pascals to about 15 Pascals. d) a growth stage to permit the oxide material to fully crystallize, the growth stage duration selected from a range of about 72 to about 120 hours, and an environmental pressure selected from a range of about 5 Pascals to about 15 Pascals, and a movement speed of the oxide material being a speed selected from a range of about 5 to about 10 mm/hr.; and e) a cool down stage to permit the grown oxide crystal to return to ambient temperature

In one aspect, a system for producing large crystals is provided. The system may include a furnace comprising a main heater and at least one after heater arranged adjacent and spaced apart from one another and a moving mechanism to move a crucible having oxide material therein through the furnace including through the main heater and the at least one after heater to produce a crystal, wherein the main heater and the at least one after heater are independently controllable by a computerized control system.

### BRIEF DESCRIPTION OF THE DRAWINGS

A more complete understanding of the present disclosure, and the attendant advantages and features thereof, will be more readily understood by reference to the following detailed description when considered in conjunction with the accompanying drawings, in which:

FIG. 1 is a block diagram of a system for producing crystals from a melt, configured according to principles of the disclosure;

FIG. 2 is a top view showing a furnace including a main heater, a first after heater and a second after heater, configured according to principles of the disclosure;

FIG. 3 is an end-on view showing the insulating arrangement of the main heater, configured according to principles of the disclosure;

FIG. 4A is an end-on view of insulation arrangement for after heater, and FIG. 4B is a side view of FIG. 4A;

FIG. 5 shows the furnace of FIG. 2 and an upper chamber and a lower chamber and related features, configured according to principles of the disclosure;

FIG. 6 shows an exemplary process for producing large oxide crystals from a melt, the process performed according to principles of the disclosure;

FIGS. 7A-7E are examples of the location of the crucible for various stages of the crystal production process, according to principles of the disclosure;

FIG. 8 shows a top view of an exemplary heater element assembly, configured according to principles of the disclosure; and

FIG. 9 is an end-on view showing an example of possible positioning of heater element assemblies in a main heater and after heater and showing possible location of a vapor shield, configured according to principles of the disclosure.

The present disclosure is further described in the detailed description that follows.

### DETAILED DESCRIPTION OF THE DISCLOSURE

The aspects of the present disclosure and the various features and advantageous details thereof are explained more fully with reference to the non-limiting aspects and examples that are described and/or illustrated in the accompanying drawings and detailed in the following description. It should be noted that the features illustrated in the drawings are not necessarily drawn to scale, and features of one aspect may be employed with other aspects as the skilled artisan would recognize, even if not explicitly stated herein. Descriptions of well-known components and processing techniques may be omitted so as to not unnecessarily obscure the aspects of the present disclosure. Each feature of one drawing may not necessarily be shown in another Figure for clarity reasons. The examples used herein are intended merely to facilitate an understanding of ways in which the present disclosure may be practiced and to further enable those of skill in the art to practice the aspects of the present disclosure. Accordingly, the examples and aspects herein should not be construed as limiting the scope of the present disclosure, which is defined solely by the appended claims and applicable law. Moreover, it is noted that like reference numerals represent similar parts throughout the several views of the drawings. The components of the drawings may not be presented to scale.

A “computer”, as used in this disclosure, means any machine, device, circuit, component, or module, or any system of machines, devices, circuits, components, modules, or the like, which are capable of manipulating data (e.g., taking input data to send an output signal that can control specific parameters) according to one or more instructions, such as, for example, without limitation, a processor, a microprocessor, a central processing unit, a proportional-integral-derivative controller, a Programmable Logic Controller, a general purpose computer, a super computer, a personal computer, a laptop computer, a palmtop computer, a notebook computer, a desktop computer, a workstation computer, a server, or the like, or an array of processors, microprocessors, central processing units, general purpose computers, super computers, personal computers, laptop computers, palmtop computers, notebook computers, desktop computers, workstation computers, servers, or the like.

Devices that are in communication with each other need not be in continuous communication with each other, unless expressly specified otherwise. In addition, devices that are in communication with each other may communicate directly or indirectly through one or more intermediaries.

Although process steps, method steps, algorithms, or the like, may be described in a sequential order, such processes, methods and algorithms may be configured to work in alternate orders. In other words, any sequence or order of steps that may be described does not necessarily indicate a requirement that the steps be performed in that order. The steps of the processes, methods or algorithms described herein may be performed in any order practical. Further, some steps may be performed simultaneously.

When a single device or article is described herein, it will be readily apparent that more than one device or article may be used in place of a single device or article. Similarly, where more than one device or article is described herein, it will be readily apparent that a single device or article may be used in place of the more than one device or article. The functionality or the features of a device may be alternatively embodied by one or more other devices which are not explicitly described as having such functionality or features.

Throughout the specification the term “comprising” shall be understood to have a broad meaning similar to the term “including” and will be understood to imply the inclusion of a stated integer or step or group of integers or steps but not the exclusion of any other integer or step or group of integers or steps. This definition also applies to variations on the term “comprising” such as “comprise” and “comprises”.

A “computer-readable medium”, as used in this disclosure, means any medium that participates in providing or storing data (for example, instructions) which may be read by a computer. Common forms of computer-readable media include, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, an EPROM, a FLASH-EEPROM, any other memory chip or cartridge, or any other medium from which a computer can read. A computer program product may be provided that stores software configured to, when read and executed by a processor, perform one or more steps of the processes described herein.

Various forms of computer readable media may be involved in carrying sequences of instructions to a computer. For example, sequences of instruction (i) may be delivered from a RAM to a processor, (ii) may be carried over a wireless transmission medium, and/or (iii) may be formatted according to numerous formats, standards or protocols, including, for example, WiFi, WiMAX, IEEE 802.11, DECT, 0G, 1G, 2G, 3G or 4G cellular standards, Bluetooth, or the like.

The terms “a,” “an,” and “the,” as used herein, are defined to mean “one or more,” unless expressly specified otherwise. The terms “including,” “having,” “comprising,” and variations thereof, as used herein, are defined to mean “including, but not limited to,” unless expressly specified otherwise.

The dimensions shown in the drawings are illustrative, and may be of different dimensions. The dimensions of the drawings are given in millimeters.

A process and system of the disclosure may be used to produce large, defect-free oxide crystals with high melting points and may utilize a water-cooled horizontal furnace with a hot zone design comprising multiple independently controllable heaters surrounded by a vapor shield and various layers of thermal insulation of varying thickness and composition. The specific design parameters of the heater, vapor shield, and insulation enable the growth of large high quality crystals. Raw materials such as sapphire crystals or alumina powder may be placed in a crucible or boat that may be positioned to ride on graphite rollers. The crucible may be pulled (or pushed) through a furnace environment surrounded by a vapor shield and insulation at a controlled rate to melt and then crystallize the raw material into a sapphire crystal. The vacuum level may be controlled by a vacuum system attached to the furnace and is typically operable to provide between about 0 Pascals to about 20 Pascals during the crystal growth stage. All of the process parameters such as power, temperature, pulling speed (i.e., movement speed), heating rates, cooling rates, chamber pressure may be controlled by a control system which may be configured to take an input from each component of the system and sends the necessary control outputs. There may be a human-machine interface (HMI) that enables an operator to control the system in real-time, as needed.

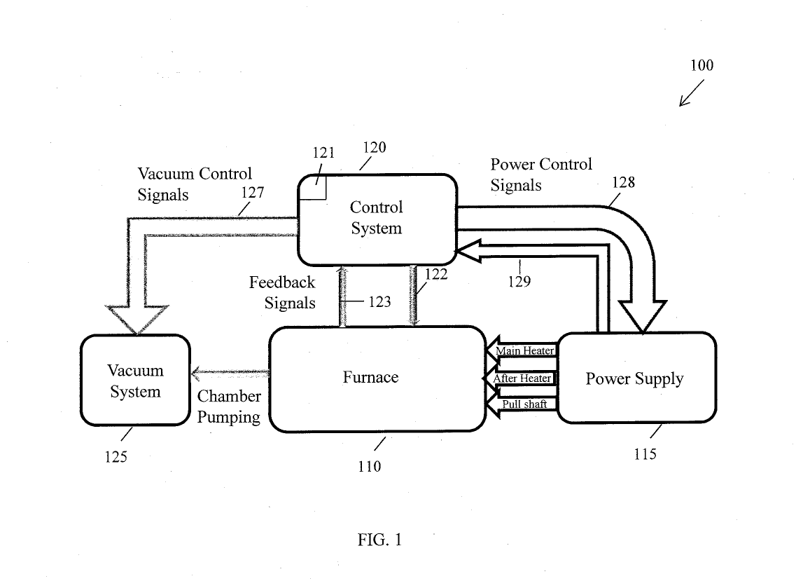

FIG. 1 is a block diagram of a system for producing crystals from a melt, configured according to principles of the disclosure. The system 100 may comprise a furnace 110 which may include multiple heating stages and heaters, a power supply 115 for powering all or some of the components of system 100, a control system 120 configured to control components of the system 100 including the furnace 100, speed of shaft 220, power supply 115 and vacuum pump 125, and any cooling or heating operations.

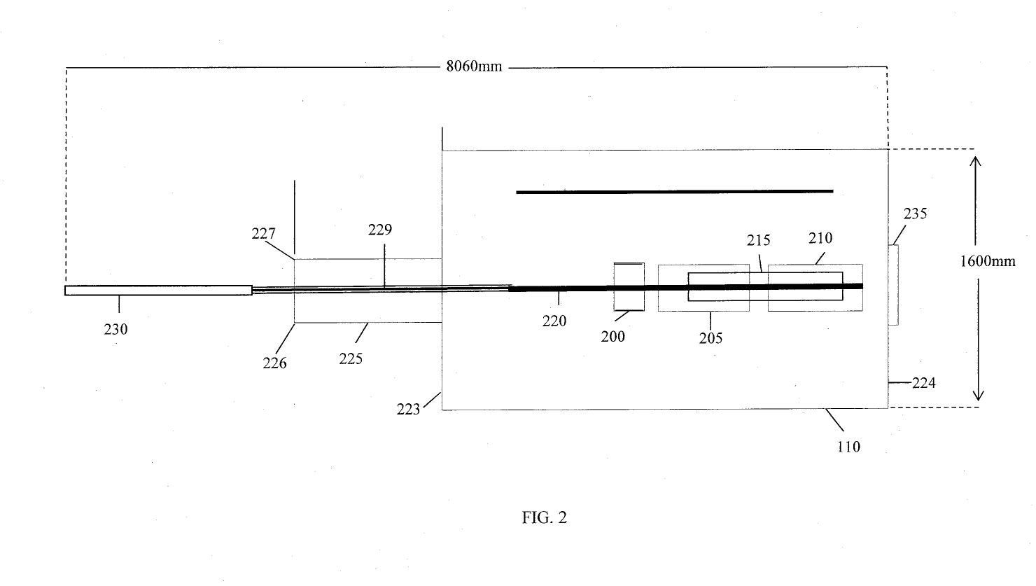

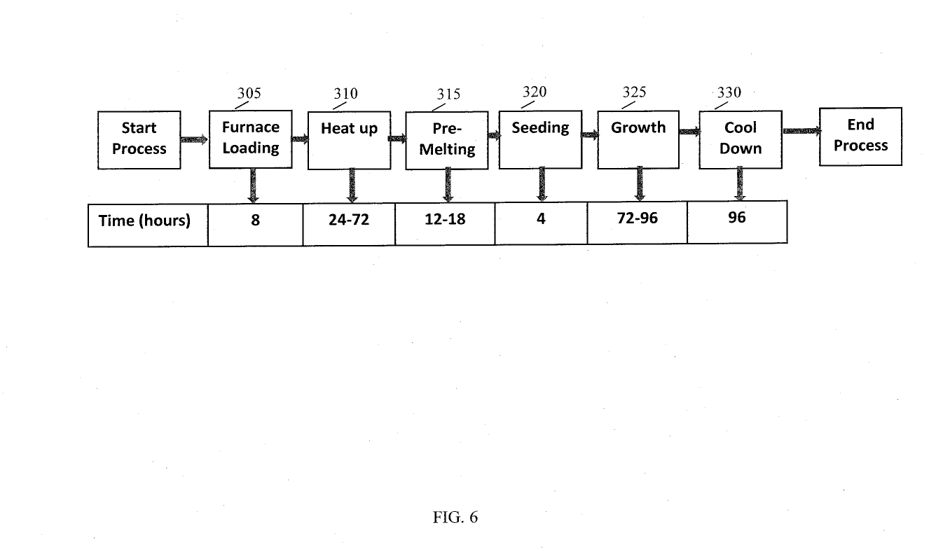

The control system 120 may be configured to include a computer 121 that is configured to control the crystal creation processes as described more fully below, and may be operatively connected to the furnace 110, the power supply 125, and the vacuum 125 for controlling each of these components. The control system 120 may control the furnace 110 by way of one or more signals 122 such as, e.g., a signal for controlling movement of moving mechanism, which may be a push/pull shaft, to propel a crucible 215 (FIG. 2) through the interior of the furnace 110. The moving mechanism may be configured to be extendable to extend into the furnace 110. The furnace 110 may be configured to provide feedback signals 123 to the control system 120 such as, e.g., temperature readings for the one or more heaters of the furnace, speed of motion of the pull shaft and vacuum pressure within the furnace. The control system 120 may monitor temperatures for all water channels (e.g., in chamber walls, in current inlet/outlets, in power supplies, etc.) to ensure stable and safe operation. The control system 120 may control the vacuum system 125 by way of vacuum control signals 127. The vacuum system 125 permits a vacuum, near vacuum or other predetermined pressure to be created in a chamber (FIG. 6, 111, 112) that encloses the furnace 110, described more fully below. The control system 120 may control via signals 128 various power operations of the power supply 115 which provides power related to the various components of the furnace 110 (such as the one or more heaters), the pull shaft, and the like. The power supply 115 may be configured to provide feedback signals 129 to the control system 120 such as, e.g., the current, the voltage, the power, the temperature of various subcomponents of the power system. The control system 120 may be configured to control movement of the crucible 215 according to a predetermined schedule and configured to control temperature of the furnace 110 according to the predetermined schedule, such as, e.g., certain stages 310, 315, 320, 325, 330, as shown in FIG. 6.

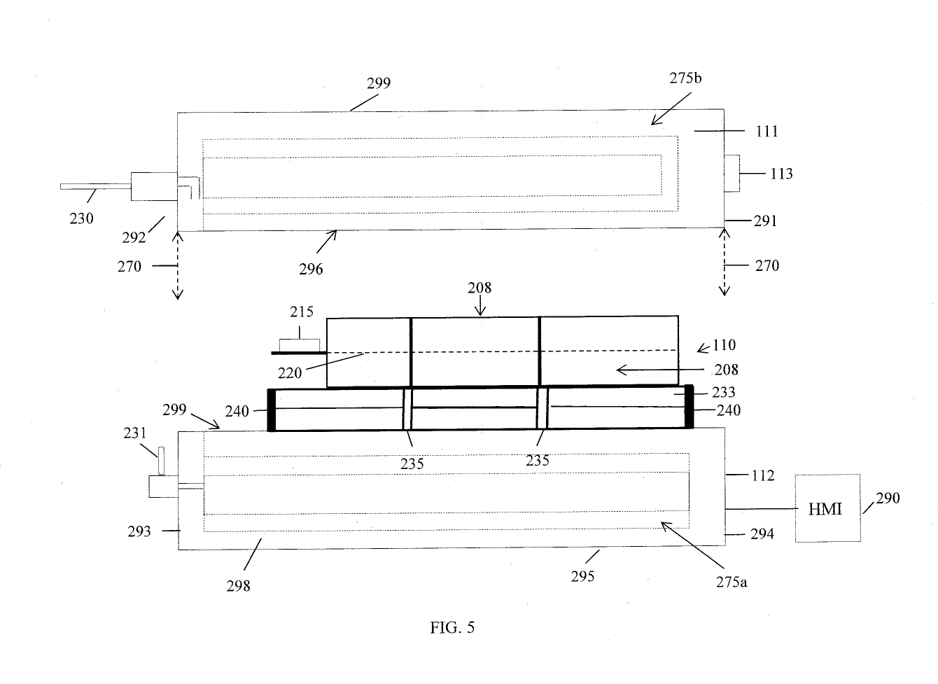

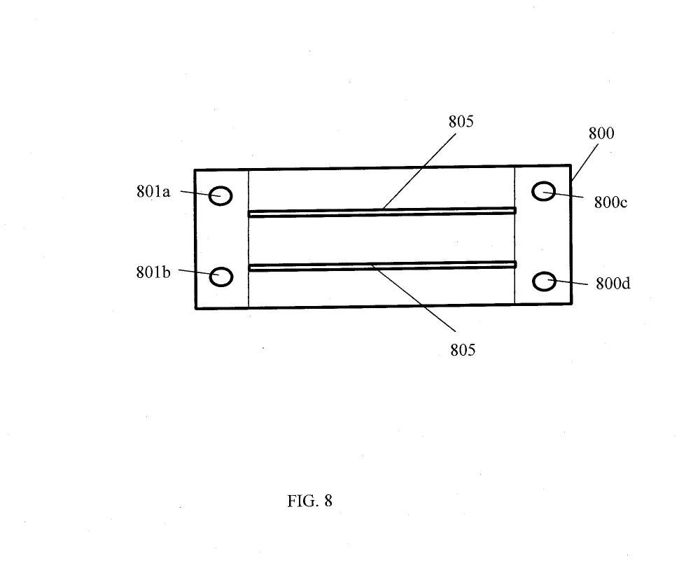

FIG. 2 is a top view showing the furnace 110 including a main heater 200, a first after heater 205 and a second after heater 210, configured according to principles of the disclosure. Also shown is a front annex 225 extending from and connected to the furnace 110, all of which are substantially sealed within a chamber (shown in FIG. 5) so that a vacuum or reduced pressure may be created for establishing a reduced pressure environment within the furnace 110 and front annex 225, including a vacuum, or partial vacuum. The furnace may have a first end 223 and a second end 224. Also, shown is a moving mechanism such as a shaft 220 for pulling and/or pushing a crucible 215 through the furnace 110 including through the main heater 200, a first after heater 205 and a second after heater 210. The shaft 220 may be positioned to align along the long axis of the furnace 110. The heaters 200, 205, 210 are configured to be positioned spaced-apart and independent of one another, but configured to operate in conjunction with one another so that the crucible 215 may move easily and continuously from one heater to another heater during the crystal production process. Each heater 200, 205, 210 may be configured to be independently controlled by control system 120. The shaft 220 may extend through an outer wall 227 of the front annex 225 and a seal 226 may be configured to seal the opening in the front annex 225 to permit the shaft 220 to be pulled or pushed while a reduced pressure environment may be maintained within the front annex 225 and furnace 110. Shaft 220 is configured to be fluid cooled such as, e.g., by water. One or more jackets 229, 230 provide housing for containing the cooling fluid flow around the shaft 220. The main heater 200 may comprise two separate heater elements, such as, e.g., shown in FIG. 8. There may be one heater element configured on the top and one on the bottom of the main heater 200.

The crucible 215 is configured to receive raw material such as, e.g., aluminum oxide and/or small sapphire crystals for forming large sapphire crystals. The crucible 215 may be propelled along the interior of the furnace 110 and the multiple heaters 200, 205, 210 by the shaft 220. The rate of movement and temperature exposures of the crucible and its contents within the furnace 110 may vary depending on the stage of the crystal growth process, as will be explained below.

The crucible 215 may be loaded with raw material by extending the shaft 220 to the second end 224 of the furnace 110 so that the crucible is accessible for loading via the door 235. Alternatively, or in addition, the entire top half of the chamber is configured to be lifted up to gain access to the components for loading the crucible and general maintenance.

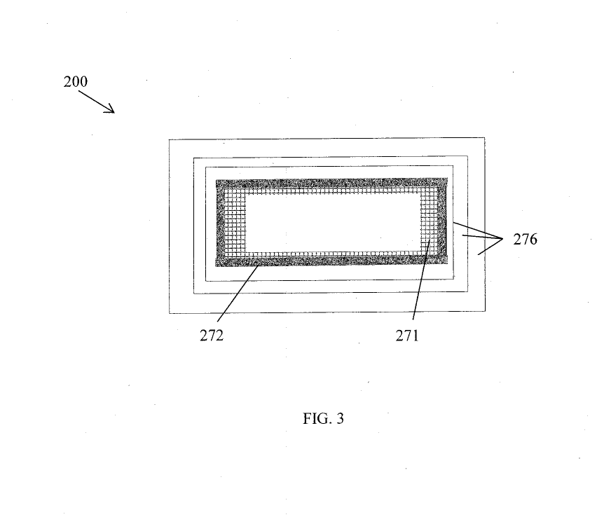

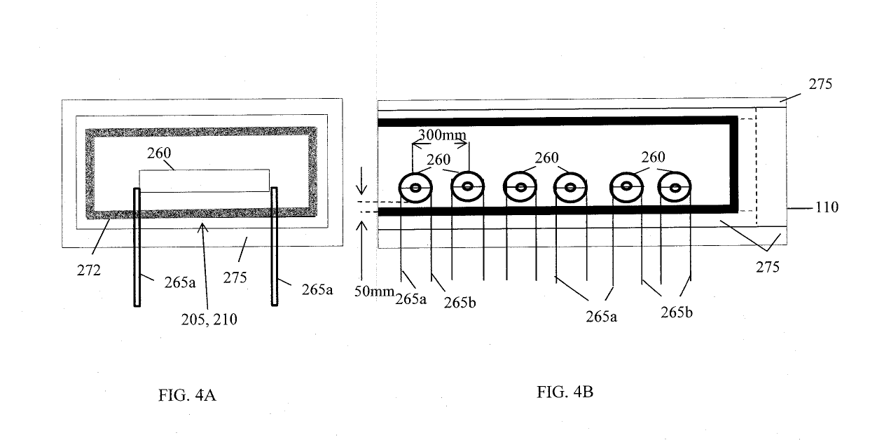

FIG. 3 is an end-on view showing the insulating arrangement of the main heater 200, and FIG. 4A is an end-on view of the insulation configured according to principles of the disclosure. The heaters 200, 205, 210 may further comprise a plurality of carbon-based material layers 276, another insulation layer 272 that may be denser insulation layer of graphite due to being closer to the heater, and an added insulation layer 271. The plurality of graphite layers 276 may be configured to be modular for replacement and provides for a snug fit by overlapping one another along the top and sides of the heaters 200, 205, 210 to minimize heat dissipation.

FIG. 4B is a side view of FIG. 4A and also shows rollers 260 and support mechanisms 265a and 265b. The rollers 260 are configured to support the crucible 215 while permitting smooth movement of the crucible 215 along the length of furnace 110, and through heaters 200, 205, 210. The rollers 260 may comprise graphite rollers. The rollers 260 are configured to cooperate with the shaft 220 as a moving mechanism for propelling the crucible 215 into and along the furnace 110.

FIG. 5 shows the furnace 110, upper chamber 111 and lower chamber 112 and related features, configured according to principles of the disclosure. The furnace 110 is shown configured with insulation 208 on the top, bottom and all sides. Within the furnace 110 are the main heater 200, first after heater 205 and second after heater 210 and associated rollers 265, as previously described. Shaft 220 and crucible 215 are also shown for illustrative purposes. The insulated furnace 110 is shown mounted upon a support structure 230. The support structure 233 is elevated by support members 240, both of which are configured within a lower chamber 112. Conduits 235 provide runs for power to the heaters 200, 205, 210 of the furnace 110.

Upper chamber 111 is configured to be raised/lowered 270 by a lift mechanism (not shown) the upper chamber 111 is configured to mate with the lower chamber 112 so that full access to the insulated furnace may be achieved. The upper chamber has a first side 292 and a second side 291, a top side 297 which may be a convex shaped dome, but may also be a rectangular type top, which together creates a hollow chamber 296 therewithin; the bottom being substantially open. When mated, the upper chamber 111 and lower chamber 112 form a sealed chamber therebetween when closed, with furnace 110 inside. The lower chamber 112 has a first end 293 and a second end 294, a bottom 295 a front side 298 and a back side 299 which form the lower chamber enclosure that contains the furnace 110. The sealed chamber formed by mated chambers 111, 112 may be evacuated by vacuum system 125 for creating a vacuum or partial vacuum environment therewithin. Also a pressurized environment may be created therewithin.

A vacuum port 231 may be configured on one of the chambers 111, 112 for connection to the vacuum system 125 to permit partial or total evacuation of the interior gas volume of the enclosed chamber formed by mated upper chamber 111 and lower chamber 112. The upper chamber 111 and/or the lower chamber 112 may be configured to be fluid cooled, e.g., water cooled. The walls of the upper chamber 111 and/or the lower chamber 112 are configured with cooling channels 275a, 275b therein for circulating cooling fluid, e.g., water, to keep the components therein cooled to a desired or manageable temperature and/or to prevent undesired heating outside the chambers 111, 112. An access port 113 may be configured in the upper chamber 111. A human-machine interface station 290 may be provided so that a human operator may interact with the control system 120 such as, e.g., but not limited to: setting parameters associated with a crystal production cycle including heater settings, pressures, heater element configurations and settings, stage duration, shaft positioning and movement, control the opening and closing of the chambers 111, 112, control the vacuum system 125, the power supply 115 and/or receive status and progress indications from the control systems.

The quality of the crystals produced may be established by controlling the crystallization front and thermal gradients within the hot zone of the furnace 110. The hot zone created by a plurality of independently controlled heaters, e.g., heaters 200, 205, 210. High quality is generally defined as a minimization or absence of bubbles, cracks, grain boundaries, and internal defects and suitable for use. Large crystals may be defined as having one or more dimensions (i.e., length, width, thickness) greater than 500×300×30 mm. The creation of large high quality oxide crystals, such as sapphire, with specific crystallographic orientations (e.g. a-plane, c-plane, m-plane, r-plane and random orientations for sapphire) is due to several features described next:

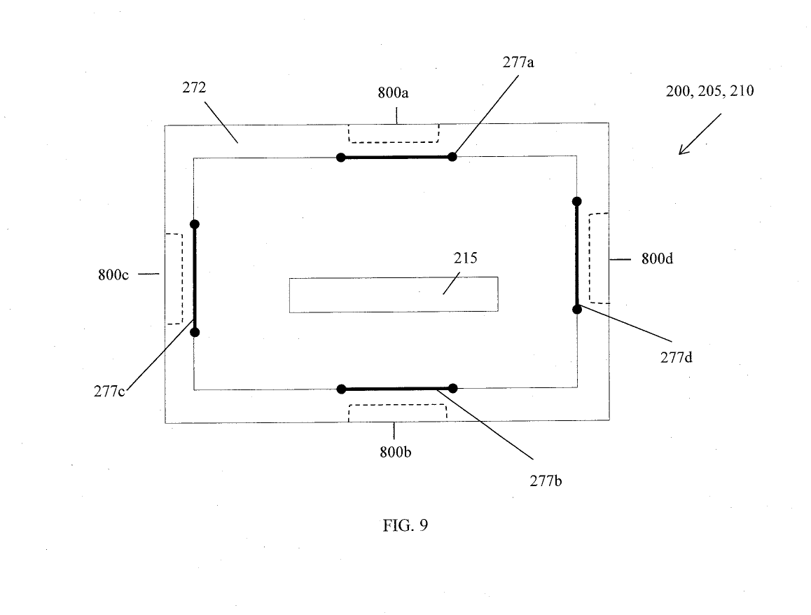

One of the traditional difficulties in creating large single crystals is that the increased crystal width or thickness may create instabilities at the solid-liquid interface, thereby preventing the formation of a uniformly shaped crystallization front that is necessary to eliminate defects. To overcome this difficulty, two or more independently controlled heating element assemblies 800 may be utilized instead of the traditional technique of employing a single large heating element. As shown in FIG. 9, the arrangement of the two or more heating element assemblies 800a-800d may be either symmetric or asymmetric above, below, and/or on the sides of the crucible 215. The total number and specific location of heating element assemblies 800a-800d within a specific heater 200, 205, 210 may vary depending on application goals. This provides the following advantages over the prior art:
An ability to independently control the heat supplied to the top, bottom, and sides of the crystal.
Improved control over the convexity of the crystallization front.
Improved control over the axial location of the crystallization front.
Under normal operating conditions the thermal gradient is spatially and temporally stable and symmetric fore and aft of the heater along the long axis
Non-uniform heating of any heater 200, 205, 210 can be applied in response to non-uniform heat dissipation within the melt due to but not limited to IR radiation emanating from the surface of the melt and convection currents within the melt.
An ability to independently replace and modify the size, shape, and length of each individual heating element assemblies 800.
The above advantages enable superior thermal control of the hot zone and control over the crystallization process compared to prior traditional techniques thus enabling the production of crystals that are both larger and of higher quality than are currently available.
Improved power utilization of the heating element assembly 800 resulting in greater energy efficiency and lower operational costs.

Due to the extremely large size of the crystals that can be grown by the process of this disclosure, the distance between the front or leading edge of a crystal being grown within the crucible 215 and a single heater, if only a single heater (e.g., only main heater 200) were to be used, would become sufficiently long to create a high temperature gradient along the length of the grown crystal; which might create stress and cracks in the grown crystal. But, to prevent this from occurring, the employment of the after heaters 205, 210 prevents this situation. One or more after heaters 205, 210 are able to supply a specific amount of heat to the grown crystal to minimize the thermal gradient and prevent stresses and cracks from building up.

Theoretically any reasonable number of after-heaters such as after heaters 205, 210 may be configured depending on the crystal length and temperature gradient that is required. The after heater(s) 205, 210 maintain a temperature gradient in the forming large crystal in the crucible 215 within a predetermined threshold to prevent stresses on the forming crystal. The after-heaters 205, 210 are configured to be controlled via an optical pyrometer whereas the main heater 200 may be controlled by the applied power from power supply 115 (e.g., setpoint is to 40 kW and not 2100 degrees C.).

Growing crystals of any size generally requires that heat dissipation be minimized. This becomes especially important for large crystal manufacturing because large crystals tend to require heaters with large internal volumes where heat dissipation and consequently thermal insulation becomes nontrivial. The system of this disclosure may be configured to utilize refractory metals, including platinum, iridium, osmium, rhenium, tantalum, tungsten, and molybdenum in addition to graphite and carbon-based composites as insulation materials. The insulation material may also contain a variety of coatings such as tungsten, tantalum carbide, or any number of carbon based coatings to improve performance, longevity, and adjust the thermal properties. The arrangement of insulation materials within the furnace 110 is designed to prevent heat loss and improve the stability of the crystallization front and the grown crystal, enabling the synthesis of large crystals free of bubbles, cracks, and grain boundaries. The refractory metals are primarily but not necessarily used to surround the heating elements 800 and the graphite materials 276 are used further away from the heater elements 800. The thickness of the insulation material varies axially along the hot zone of the furnace to minimize heat loss at specific locations of the heaters 200, 205, 210. This configuration provides the following advantages over traditional systems:
The positioning and thickness of the insulation prevents the formation of cracks and grain boundaries during all stages of crystal growth (heating, growth, cooling).
Stabilization of the solid-liquid interface and the formation of a convex crystallization front with respect to the grown crystal.
The use of graphite and carbon composites significantly reduces both the weight and cost compared to designs that implement only refractory metals which are heavier and significantly more expensive.
The insulation is designed to be modular so that pieces fit together easily and efficiently, minimizing heat loss due to unnecessary gaps in the components. Additionally, this allows for quick and easy replacement of any individual parts.

The configuration of the heaters 200, 205, 210 and configuration of the associated insulation as described in this disclosure is necessary, but may be insufficient if considered alone, for growing large oxide crystals of high purity and quality. But, when combined with a set of growth parameters that takes advantage of the superior hot zone design of the system of the disclosure, a superior process and system can be achieved. For example, the crucible 215 is constructed comprising a refractory metal selected from the group comprising: platinum, iridium, osmium, rhenium, tungsten, and molybdenum that initially has a non-constant width for between about 15% to about 35% of the total length tapering out to constant width that is between about 30% and about 85% of the total length. The growth of the crystal may be controlled by several factors such as the rate and duration of pulling of the crystal through the heaters 200, 205, 210 by the shaft 220, the rate at which power is supplied to the heaters 200, 205, 210, the duration of the power supplied to the heaters 200, 205, 210, and the location and shape of the crystallization front. During the initial stage of crystal growth the rate of movement of the crucible through the heater may be between about 4 and 12 mm/hr. As the crystallization front approaches the section of the crucible with constant width the rate of movement may be adjusted to between about 5 and about 8 mm/hr., for example. Once in the constant width section of the crucible, the pulling rate may be maintained at a predetermined rate, e.g., between about 5 and about 15 mm/hr for the duration of the growth. The rate may vary by an operator as deemed warranted. Sufficient power is supplied to the heaters to maintain the convex crystallization front with respect to the crystal (as opposed to the liquid melt). Different amounts of power may be applied to the top, bottom, and side heaters, Additionally, the power ratio for the top and bottom heater elements 800a and 800b may play a significant role on the quality of the grown crystal and varies typically between 3:1 (top:bottom) and 2:1. This capability may provide the following advantages over the current traditional techniques:
Improved crystal quality (minimization of bubbles, cracks, and grain boundaries) by varying the growth rate along the axis of the crucible in a controlled manner.
Increase in crystal size due to enhanced control of growth rate and crystallization front.
Two methods for controlling the growth rate of the crystal: (i) the pulling rate and (ii) the rate of applied power which controls the crystallization front and consequently the growth rate.

FIG. 6 shows an exemplary process for producing large oxide crystals from a melt, the process performed according to principles of the disclosure. The process of FIG. 6 may be performed using, e.g., the system of FIGS. 1-5. The process of FIG. 6 shows for each stage of the process an example of typical times (or a range of time) in hours of the respective stage thereby providing a pre-determined schedule. The pre-determined schedule may also include controlling the temperature of the furnace, the pressure of the furnace, and the speed (e.g., in mm/hr) of the movement of the crucible 215 as propelled by shaft 220. The stages include: furnace loading stage 305, heat-up stage 310, pre-melting stage 315 (in which the material is melted fully but not producing a single crystal), seeding stage 320, growth stage 325, and cool-down stage 330. Each step may vary in longevity (hours to days), pressure level, temperature and perhaps, heater power. A pre-determined time(s), pre-determined speeds, pre-determined pressure levels, pre-determined temperature, pre-determined heater power may be established based on specific goals for crystal production.

The furnace loading stage 305 may be performed with substantially ambient temperature and pressures (or perhaps more than ambient pressure), and typically involves loading the crucible 215 with raw material through door 235 or with upper chamber 111 lifted up, and may include selecting parameters for a production cycle, as necessary. This stage time may be quite variable, as it is dependent on human activity.

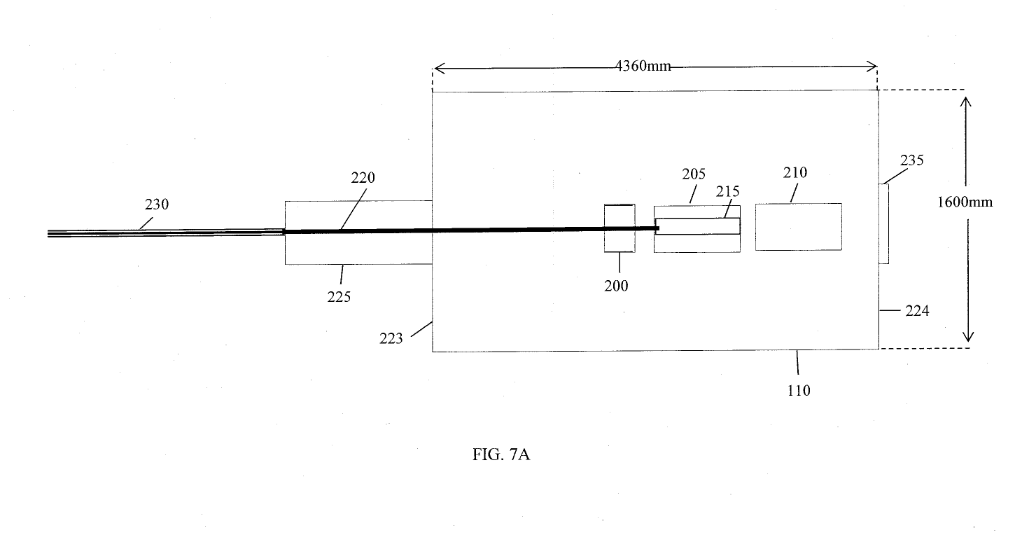

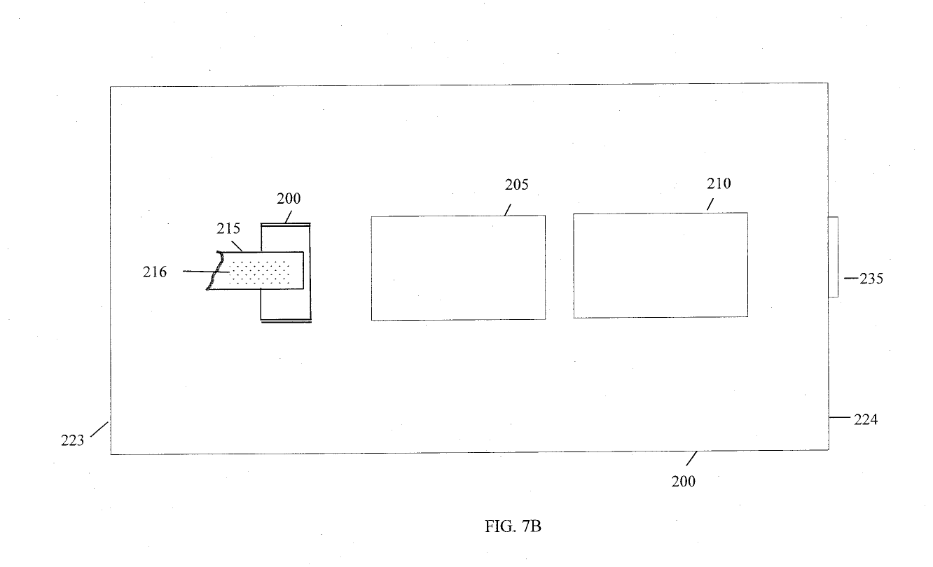

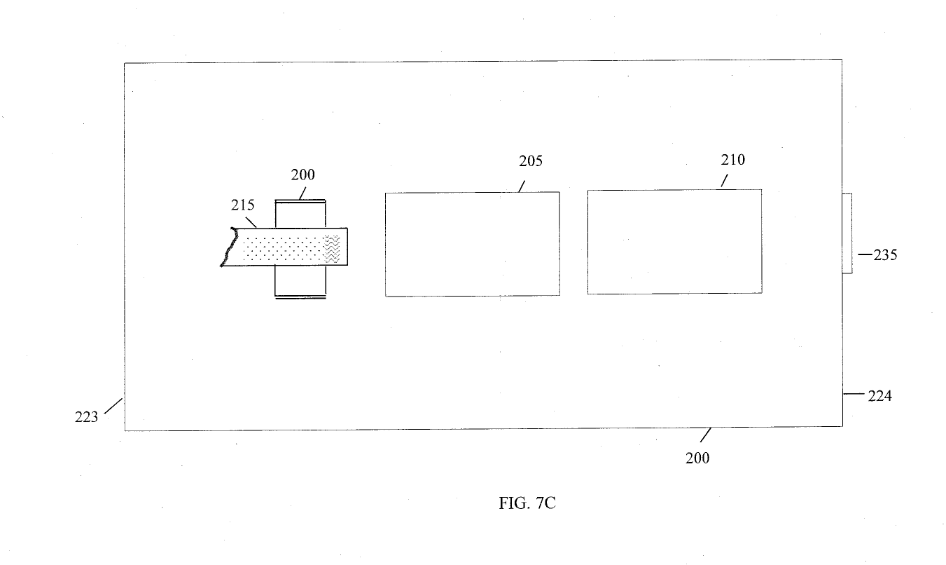

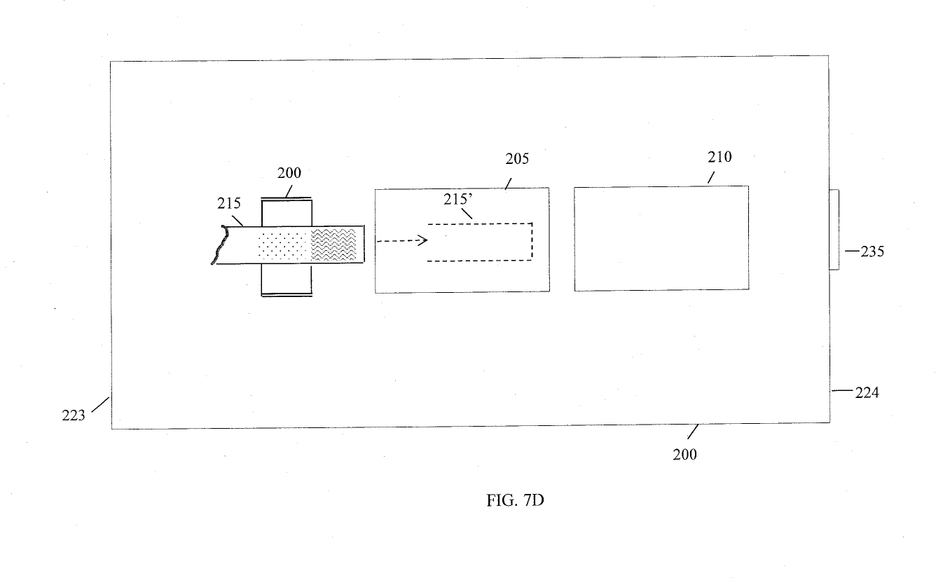

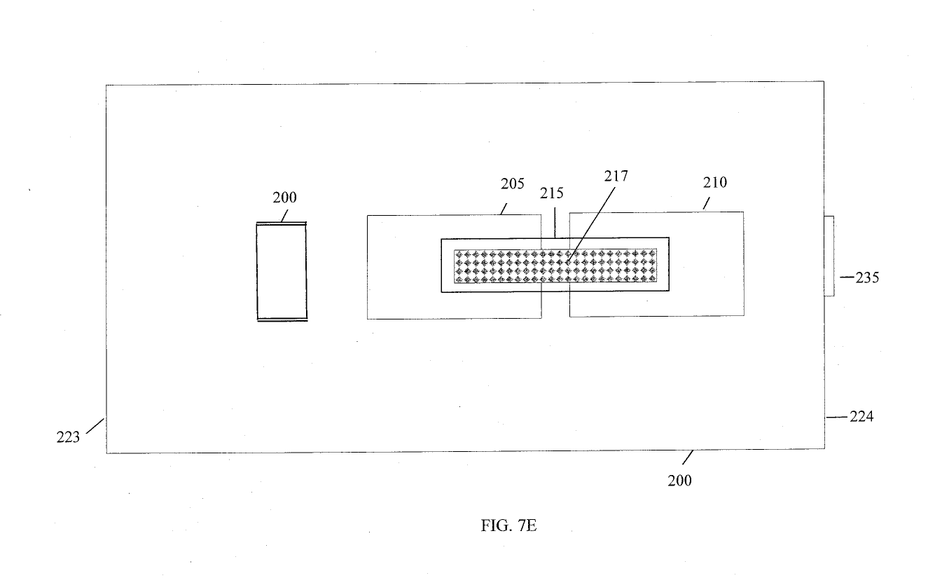

The heat up stage 310 typically involves positioning the crucible 215 with raw materials 216 approximately as shown in FIG. 7A. During pre-melting, the crucible may move from right to left entering under the main heater 200. The heaters 200, 205, 210 may be powered up and activated to establish operating temperatures, e.g., about 20 to about 2200° C. A vacuum may also be created, e.g., about 0 to about 20 Pascals. This stage may have a time of about 24 to about 72 hours.

The pre-melting stage 315 involves movement of the rear edge of the crucible along (right to left) to an approximate position as shown in FIG. 7B. This stage may have a time of about 12-18 hours, a temperature of about 2200° C., a pressure of about 10-20 Pascals, and a pulling speed selected from a range of about 8-15 mm/hr. This stage 315 permits the raw material 216 to begin to liquefy. Part of the raw material 216 may be solid and part may be liquid.

The seeding stage 320 involves movement of the leading edge of the crucible 215 along to an approximate position as shown in relation to FIG. 7C. This stage may have a time of about 4 hours, a temperature of about 2200° C., a pressure of about 5-15 Pascals, and a pulling speed of selected from the range of about 8-15 mm/hr. This stage is where crystal formation begins at the leading edge of the crucible 215 since the leading edge of the crucible exits the main heater 200, it begins to cool somewhat to permit the beginning of crystallization, while the melt still in the main heater 200 remains liquid. The crystallization process begins from a pre-positioned seed of known crystallographic orientation, which is not fully melted. This seeding provides crystal growth in a preselected orientation (e.g., a-, c-, m-, r-planes).

The growth stage 325 involves movement of the leading edge of the crucible 215 to a position approximately as shown in FIG. 7D, and perhaps even further, to begin entry into the first after heater 205. (At the end of growth the majority of the crystal will be over the first after heater 205, shown as 215′.) This stage may have a time range selected from about 72 to 120 hours, a pulling speed may be selected from the range of about 5 mm/hr to about 10 mm/hr, with a temperature of about 2200° C., and a pressure selected from the range of about 5 to about 15 Pascals. At this stage, the crystal grows in size. As the crucible moves along being propelled by the shaft 220, different parts of the crucible 215 and the contents therein may be undergoing different heat experiences, permitting the crystal to fully grow in size and crystallize.

The cool down stage 330 involves movement of the leading edge of the crucible 215 to a position approximately as shown in FIG. 7E, or further. Generally, the entire crucible 215 will have substantially entered the after heater(s) 205, 210. This stage 330 may have a time of about 96-144 hours, a pulling speed of 0 mm/hr, with a temperature decreasing from about 2200° C. to about 20° C. (ambient), and a pressure range returning to about 1-5 Pascals, and the pulling speed is essentially stopped, i.e., 0 mm/hr. The final crystal 217 is permitted to cool down.

FIG. 8 shows a heater element assembly 800, configured according to principles of the disclosure. The heater element assembly 800 may comprise heater elements 805 which may be constructed from various refractory materials including but not limited to tungsten and its alloys, carbon based materials such as carbon fiber composite and graphite. In one aspect, the maximum heater temperature is approximately 2300 to about 2700° C. Additionally, coatings may be applied to the heater elements 805 to improve performance, durability, and longevity of the heater elements 805. Coatings may include tungsten (i.e. tungsten coated graphite heater), tantalum carbide, and various polymorphs of carbon such as vitreous carbon (glassy carbon) that are non-graphitizing. The heaters element 805 may be designed to operate at a range of voltages (about 0 to about 80 V) and currents (about 0 A to about 8000 A) by modifying the heater length, cross sectional area, and thickness to achieve the necessary resistance.

FIG. 9 is an end on view showing an example of possible positioning of heater element assemblies 800 in heater 200, 205, 210 and possible locations of one or more vapor shields 277a-277d, configured according to principles of the disclosure. As shown in FIG. 9, a top heater element assembly 800a and bottom heater element assembly 800b may be employed to control the growth interface and melting process with the side heating accomplished by either a top heater element assembly 800a, a bottom heater element assembly 800b, or shared between the two. Top heater element assembly 800a and bottom heater element assembly 800b are configured for the main heater 200 and after heater 205, 210 in a preferred implementation. In some implementations, independently controllable side heater assemblies 800c and 800d may also be employed. Vapor shield 277a may be positioned between the top heater element assembly 800a and the crucible 215 containing the oxide material to minimize oxide vapors from reaching the heater elements 805, which can damage or decrease the useful life of the heater elements 805. Likewise, vapor shield 277b may be positioned between the bottom heater element assembly 800b and the crucible 215. Similarly, when side heater assemblies 800c, 800d are employed, then corresponding vapor shields 277c and 277d may be positioned between the side heater assemblies 800c, 800d and the crucible 215. The vapor shields 277a-277d may comprise a composite fiber material, a tungsten material, or other heat resistant material that is suitable to separate the heater assemblies 800a-800d from the vapors produced by the hot oxide in the crucible 215. The vapor barriers 277a-277b minimize exposure of the heater elements 805 to the oxide vapors produced by the hot oxide material in the crucible 215 and thereby prolongs the life of the heater elements. Shaft 220 for moving the crucible 215 is not shown in FIG. 9.

In some implementations, side element assemblies 800c and 800d may be optionally utilized. The heater element assembly 800 may be mounted to a heater 200, 205, 210 using mounts 801a-801d, some of the mounts 801a-801d may serve as electrical connections.

One significant difference between traditional systems and processes and the system and process of this disclosure is the inclusion of a vapor shield, one or more after heaters, and pyrometer controlled heating for certain stages. All of these features combine to permit producing large crystals such as sapphire crystals. It should be noted that the absence of these features in the systems of the prior art is correlated with an absence of large, thick (>1″) sapphire crystals currently in the marketplace.

The crystals produced by the system and method described herein are of high quality (essentially defect free) and large size of a least 500 mm in length×300 mm in width×30 mm in thickness. The crystals may be grown to about 1000 mm in length×about 500 mm in width×about 75 mm in thickness. Of course, other dimensions that may range between these sizes are also possible (e.g., a range between about 500 mm and about 1000 mm in length, a range between about 300 mm and about 500 mm in width, and a range between about 30 mm and about 75 mm in thickness), as well as smaller or larger dimensions, utilizing the principles herein.

While the invention has been described in terms of examples, those skilled in the art will recognize that the invention can be practiced with modifications and in the spirit and scope of the appended claims.

What is claimed is:

1. A process for producing large substantially defect free oxide crystals, the process comprising the steps of:
creating a pressurized or evacuated environment for heating a crucible having oxide material therein;
moving the crucible from a main heater to at least one after heater on a pre-determined schedule, wherein the main heater and the at least one after heater are configured spaced apart from one another and configured to be independently controllable to heat the oxide material;
adjusting the pressure of the environment at least once during the process; and
cooling the oxide material to produce a large oxide crystal.

2. The process of claim 1, further comprising adjusting a rate of movement of the oxide material during the movement step.

3. The process of claim 1, wherein the main heater melts the oxide material to produce a melt and the spaced apart at least one after heater maintains a temperature gradient within a pre-determined threshold as the oxide is moved from the main heater through the at least one after heater to prevent stress in the crystal.

4. The process of claim 1, wherein the step of moving further includes moving the crucible into the main heater to melt the oxide material to create a melt.

5. The process of claim 4, wherein the step of moving permits a crystal to grow from the melt at a location between the main heater and the at least one after heater.

6. The process of claim 1, wherein the produced large oxide crystal is at least 500 mm in length, at least about 300 mm in width and at least about 30 mm in thickness.

7. The process of claim 1, wherein the large oxide crystal is a sapphire.

8. The process of claim 1, further comprising the step of seeding the oxide material to grow a crystal having a desired crystal orientation

9. A process for producing large, defect-free oxide crystals with high melting point, the process comprising the steps of:
utilizing a fluid-cooled horizontal furnace with a hot zone produced by a plurality of independently controllable heaters, each heater surrounded by a vapor shield and a plurality of thermal insulation layers to melt oxide material and to crystallize and grow the melted oxide into a large oxide crystal; and
cooling the grown large oxide crystal to ambient temperature.

10. The process of claim 9, wherein the utilizing step includes adjusting pressure in the fluid cooled horizontal furnace.

11. The process of claim 9, wherein the utilizing step includes the following stages:
a) a heat up stage to heat the oxide material, the heat up stage ranging in duration time selected from the range of about 24 to about 72 hours wherein a temperature of the fluid-cooled horizontal furnace is selected from a range between about 20° C. and about 2200° C. and an environmental pressure selected from a range from about 5 Pascals to about 20 Pascals;
b) a pre-melting stage to melt the oxide material, the pre-melting stage duration is selected from a range from about 12 to about 18 hours and an environmental pressure is selected from a range of about 10 Pascals to about 20 Pascals, and a speed of movement of the oxide material though the hot zone is about 60 mm/hr.;
c) a seeding stage to permit the melted oxide material to begin to crystallize, the seeding stage of oxide movement speed selected from the range of about 8 mm/hr to about 15 mm/hr. and an environmental pressure selected from a range from about 5 Pascals to about 15 Pascals;
d) a growth stage to permit the oxide material to fully crystallize, the growth stage duration selected from a range of about 72 to about 120 hours, and an environmental pressure selected from a range of about 5 Pascals to about 15 Pascals, and an movement speed of the oxide material being a speed selected from a range of about 5 to about 10 mm/hr.; and
e) a cool down stage to permit the grown oxide crystal to return to ambient temperature.

12. A system for producing large crystals, comprising:
a furnace comprising a main heater and at least one after heater arranged adjacent and spaced apart from one another; and
a moving mechanism to move a crucible having oxide material therein through the furnace including through the main heater and the at least one after heater to produce a crystal,
wherein the main heater and the at least one after heater are independently controllable by a computerized control system.

13. The system of claim 12, wherein the moving mechanism comprises a shaft that is extendable into the furnace.

14. The system of claim 13, wherein the shaft is fluid cooled.

15. The system of claim 13, wherein the moving mechanism further includes a plurality of rollers to permit the crucible to travel along an interior of the furnace.

16. The system of claim 12, wherein the at least one after heater comprises a plurality of after heaters.

17. The system of claim 12, wherein the main heater and the at least one after heater comprises a plurality of heating elements.

18. The system of claim 17, further comprising a plurality of vapor shields configured within the main heater and the at least one after heater, each vapor shield configured to minimize oxide vapors from the oxide material from reaching the plurality of heating elements.

19. The system of claim 12, further comprising a chamber that is configured to enclose the furnace and moving mechanism, wherein the chamber comprises two mateable portions and at least one portion is movable for gaining access to the furnace.

20. The system of claim 19, wherein the chamber is configured to be pressurized.

21. The system of claim 19, wherein at least one of the two portions is fluid cooled.

22. The system of claim 12, further comprising a computerized control system to control the main heater, the at least one after heater and the moving mechanism.

23. The system of claim 22, wherein the computerized control system is configured to control movement of the crucible according to a predetermined schedule and configured to control temperature of the furnace according to the predetermined schedule.

24. The system of claim 12, wherein the produced crystal is at least 500 mm in length, at least about 300 mm in width and at least about 30 mm in thickness.

25. A crystal produced by the process of claim 1.
